(19) United States
(12) Patent Application Publication
(10) Pub. No.: US 2010/0327329 A1
(43) Pub. Date: Dec. 30, 2010

(54) SEMICONDUCTOR DEVICE AND METHOD OF FABRICATING THE SAME

(76) Inventor: Hiroshi ITOKAWA, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/816,890

(22) Filed: Jun. 16, 2010

(30) Foreign Application Priority Data
Jun. 25, 2009 (JP) 2009-150755

(51) Int. Cl. H01L 29/04; H01L 29/78; H01L 21/336

(52) U.S. Cl. 257/255; 438/198; 438/300; 438/296; 257/413; 257/E29.255; 257/E21.409; 257/E29.004

(57) ABSTRACT

According to one embodiment, a semiconductor device includes a transistor, an element isolation insulating film, and a metal silicide layer. The transistor contains a gate electrode and an epitaxial crystal layer. The epitaxial crystal layer is formed on at least one side of the gate electrode in the semiconductor substrate and includes a facet having a different plane direction from a principal plane of the semiconductor substrate. The element isolation insulating film contains a lower layer and an upper layer. A horizontal distance between the upper layer and the gate electrode is smaller than a horizontal distance between the lower layer and the gate electrode. A part of the upper layer contacts with the facet. The metal silicide layer is formed on an upper surface of the epitaxial crystal layer and on a region of the facet above a contact portion of the facet with the upper layer.

### CROSS-REFERENCE TO RELATED APPLICATIONS

This application is based upon and claims the benefit of priority from prior Japanese Patent Application No. 2009-150755, filed on Jun. 25, 2009, the entire contents of which are incorporated herein by reference.

### FIELD

Embodiments described herein relate generally to a semiconductor device and a method of fabricating the same.

### BACKGROUND

In recent years, a semiconductor device to which strained silicon technique using selectively epitaxial crystal growth technique is introduced has been disclosed.

According to a conventional semiconductor device, a Si substrate is etched in order to form recesses, and then SiGe crystals having a different lattice constant from Si crystal constituting the Si substrate is selectively epitaxial grown in the recesses and become part of source/drain regions. As a result, the SiGe crystals add stress to a channel region between the source/drain regions, thus strain (compressive strain or tensile strain) is generated in the channel region. This can improve mobility of electric charges in the channel region.

However, when SiGe crystal is grown, a crystal face called a facet appears on the SiGe crystal due to difference between crystal growth rates of different plane directions. As a result, a gap is formed between the SiGe crystal and an element isolation insulating film.

Accordingly, when surfaces of the SiGe crystal is silicided, metal film used silicidation may go into the gap between the SiGe crystal and the element isolation insulating. As a result, a metal silicide layer formed by the silicidation may reach a position in the SiGe crystal near to a bottom thereof or a position in a Si substrate under the SiGe crystal. Therefore, a problem of that junction leakage is easily generated occurs.

When the metal silicide layer contacts the Si substrate under the SiGe crystal, the silicidation rapidly progress from the contact portion toward an inside of the Si substrate because the metal silicide composed of compound of SiGe with metal is thermodynamically unstable. Therefore, junction leakage is more easily generated.

A technique for solving this problem is disclosed, for example, in JP-A-2007-227721. According to the technique, formation of a metal silicide on a facet is prevented by forming a metal film used for silicidation on a SiGe crystal after an insulating film is embedded into a gap between the facet and an element isolation insulating film.

However, according to the technique, there is a problem of that it is difficult to selectively embed the insulating film into the gap between the facet and the element isolation insulating film and a problem of that electric resistance of the source/drain regions may increase due to decrease of sum of area of the metal silicide.

### BRIEF DESCRIPTION OF THE DRAWING

FIG. 1 is a cross sectional view of a semiconductor device according to an embodiment;

FIGS. 2A to 2L are cross sectional views showing processes for fabricating the semiconductor device according to the embodiment; and

FIGS. 3A and 3B are enlarged view around a contact portion of an epitaxial crystal layer with an upper layer of an element isolation insulating film.

### DETAILED DESCRIPTION

In general, according to one embodiment, a semiconductor device includes a transistor, an element isolation insulating film, and a metal silicide layer. The transistor contains a gate electrode and an epitaxial crystal layer. The gate electrode is formed on a semiconductor substrate via a gate insulating film. The epitaxial crystal layer is formed on at least one side of the gate electrode in the semiconductor substrate and includes a facet having a different plane direction from a principal plane of the semiconductor substrate. The element isolation insulating film is formed in the semiconductor substrate and electrically isolates the transistor from other elements. The element isolation insulating film contains a lower layer and an upper layer on the lower layer. A horizontal distance between the upper layer and the gate electrode is smaller than a horizontal distance between the lower layer and the gate electrode. A part of the upper layer contacts with the facet. The metal silicide layer is formed on an upper surface of the epitaxial crystal layer and on a region of the facet above a contact portion of the facet with the upper layer.

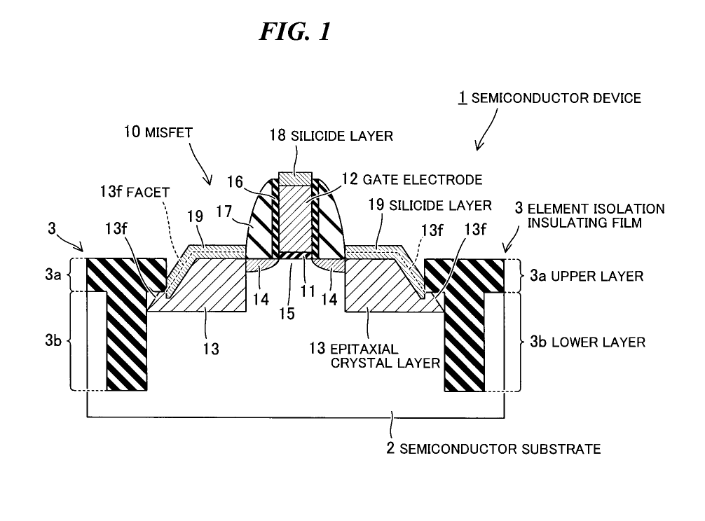

FIG. 1 is a cross sectional view of a semiconductor device 1 according to an embodiment. The semiconductor device 1 contains Metal Insulator Semiconductor Field Effect Transistor (MISFET) 10 formed on a device-forming region. The device-forming region is a region that is surrounded by an element isolation insulating film 3 on a semiconductor substrate 2.

The MISFET 10 contains a gate electrode 12 formed on a semiconductor substrate 2 via a gate insulating film 11, epitaxial crystal layers 13 formed in regions in the semiconductor substrate 2 on both sides of the gate electrode 12 and functioning as deep regions of source/drain regions, extension regions 14 of the source/drain regions, a channel region 15 between the extension regions 14 and under the gate insulating film 11, an offset spacer 16 formed on side surfaces of the gate electrode 12, and a gate sidewall 17 formed on side surfaces of the offset spacer 16.

In addition, a silicide layer 18 is formed on a surface of the gate electrode 12, and silicide layers 19 are formed on surfaces of the epitaxial crystal layers 13.

The semiconductor substrate 2 is made of crystal consisting mainly of Si, such as Si crystal.

The element isolation insulating film 3 is made of insulating material such as SiO₂ and has, for example, Shallow Trench Isolation (STI) structure. In addition, the element isolation insulating film 3 contains a lower layer 3b and an upper layer 3a on the lower layer 3b.

As shown in FIG. 1, a horizontal distance between the upper layer 3a and the gate electrode 12 (a horizontal distance between a horizontal edge of the upper layer 3a on the gate electrode 12 side and a horizontal edge of the gate electrode 12 on the element isolation insulating film 3 side) is smaller than a horizontal distance between the lower layer 3b and the gate electrode 12 (a horizontal distance between a horizontal edge of the lower layer 3b on the gate electrode 12 side and a horizontal edge of the gate electrode 12 on the element isolation insulating film 3 side). Furthermore, a part of the end of the upper layer 3a on the gate electrode 12 side contacts the epitaxial crystal layer 13. Note that, as long as meeting the above condition, the structure of the element isolation insulating film 3 is not limited to one shown in FIG. 1.

The gate insulating film 11 is made of, for example, SiO₂, SiON or high-dielectric constant material (e.g., Hf-based material such as HfSiON, HfSiO or HfO, Zr-based material such as ZrSiON, ZrSiO or ZrO, Y-based material such as Y₂O₃, or La₂O₃).

The gate electrode 12 is made of, for example, Si-based polycrystal such as Si polycrystal and contains a conductivity type impurity. When the conductivity type impurity is an n-type impurity, As, P or the like is used. Furthermore, when the conductivity type impurity is a p-type impurity, B, BF₂ or the like is used. In addition, the gate electrode 12 may be a metal gate electrode made of metal such as TiN, WN or TaC, furthermore, may have a structure of two layers composed of a metal layer and a Si-based polycrystalline layer thereon. Note that, when the gate electrode 12 is a metal gate electrode, the silicide layer 18 on the gate electrode 12 is not formed.

The epitaxial crystal layer 13 is made of Si-based single crystal consisting mainly of Si, such as Si single crystal, SiGe single crystal or SiC single crystal, growing using a surface of the semiconductor substrate 2 as a base.

In addition, the epitaxial crystal layer 13 includes a conductivity type impurity and functions as a part of the source/drain region. When the conductivity type impurity is an n-type impurity, As, P or the like is used. Furthermore, when the conductivity type impurity is a p-type impurity, B, BF₂ or the like is used.

When the epitaxial crystal layer 13 is formed, the conductivity type impurity can be introduced to a crystal at the same time as epitaxially growth of the crystal (in-situ doping). Therefore, a concentration distribution of the conductivity type impurity in the epitaxial crystal layer 13 is more homogeneous than that in a source/drain region formed by ion-implantation.

In addition, when crystal having a larger lattice constant than the crystal constituting the semiconductor substrate 2 is used for the epitaxial crystal layer 13, compressive strain in the channel direction can be generated in the channel region 15 of the semiconductor substrate 2, thereby increasing mobility of holes in the channel region 15. Accordingly, when the MISFET 10 is a p-type tramsistor, performance thereof can be improved.

For example, when the semiconductor substrate 2 is made of Si crystal, use of SiGe crystal having a larger lattice constant than Si crystal for the epitaxial crystal layer 13 can increase performance of the p-type MISFET 10. Note that, a Ge density of the SiGe crystal is preferably 20-40 atom %. Ge densities lower than 20 atom % is too low to generate enough strain in the channel region 15, and Ge densities higher than 40 atom % tends to increase crystal defects in the SiGe crystal.

In addition, when crystal having a smaller lattice constant than the crystal constituting the semiconductor substrate 2 is used for the epitaxial crystal layer 13, tensile strain in the channel direction can be generated in the channel region 15 of the semiconductor substrate 2, thereby increasing mobility of electron s in the channel region 15. Accordingly, when the MISFET 10 is an n-type transistor, performance thereof can be improved.

For example, when the semiconductor substrate 2 is made of Si crystal, use of SiC crystal having a smaller lattice constant than Si crystal for the epitaxial crystal layer 13 can increase performance of the n-type MISFET 10. Note that, a C density of the SiC crystal is preferably 1-2 atom %. C densities lower than 1 atom % is too low to generate enough strain in the channel region 15, and C densities higher than 2 atom % tends to increase crystal defects in the SiC crystal.

In addition, the epitaxial crystal layer 13 has a facet 13f having a different plane direction from a principal plane of the semiconductor substrate 2. The facet 13f is a plane appearing due to difference between crystal growth rates of different plane directions. Furthermore, a gap is formed between the facet 13f and the element isolation insulating film 3. The reason why the facet 13f appears in an area next to the element isolation insulating film 3 is that epitaxial crystal growth is not generated from a surface of the element isolation insulating film 3.

For example, when the plane direction of the principal surface of the semiconductor substrate 2 is {100} and the channel direction (which is equal to a gate-length direction of the gate electrode 12) is <110>, the plane direction of the facet 13f is {111}. Here, {100} represents (100) and plane directions equivalent to (100), {111} represents (111) and plane directions equivalent to (111), and <110>represents [110] and directions equivalent to [110].

The dotted lines in the silicide layers 19 in FIG. 1 shows outlines of the epitaxial crystal layers 13 before formation of the silicide layers 19. The Silicide layer 19 is formed on an upper surface of the epitaxial crystal layer 13 and on a region of the facet 13f above a contact portion of the facet 13f with the upper layer 3a.

Note that, the epitaxial crystal layer 13 having the facet 13f may be formed only on one side of the gate electrode 12.

The extension region 14 is a shallow and low-concentrated region of the source/drain region, and formed by, for example, implantation of a conductivity type impurity into the semiconductor substrate 2 by ion implantation technique. When the conductivity type impurity is an n-type impurity, As, P or the like is used. Furthermore, when the conductivity type impurity is a p-type impurity, B, BF₂ or the like is used.

The offset spacer 16 and the gate sidewall 17 are made of insulating material such as SiO₂ or SiN. In addition, the gate sidewall 17 may have a structure of two layer made of, e.g., SiN and SiO₂, or furthermore, a structure of three or more layers.

The silicide layer 18 is made of metal silicide that is compound of metal, such as Ni, Pt, Co, Er, NiPt, Y, Pd, Ir, with Si-based crystal constituting the gate electrode 12.

The silicide layer 19 is made of metal silicide that is compound of metal, such as Ni, Pt, Co, Er, NiPt, Y, Pd, Ir, with Si-based crystal constituting the epitaxial crystal layer 13.

The Silicide layer 19 is not formed on a region of the facet 13f below the contact portion of the facet 13f with the upper layer 3a. Thus, a position of a lowest portion of the silicide layer 19 is higher than if the silicide layer 19 is formed on the entire surface of the facet 13f. Therefore, the lowest portion of the silicide layer 19 is located in the epitaxial crystal layer 13, and the silicide layer 19 does not contact with the semiconductor substrate 2 under the epitaxial crystal layer 13.

An example of a method of fabricating the semiconductor device 1 according to the present embodiment will be described hereinafter.

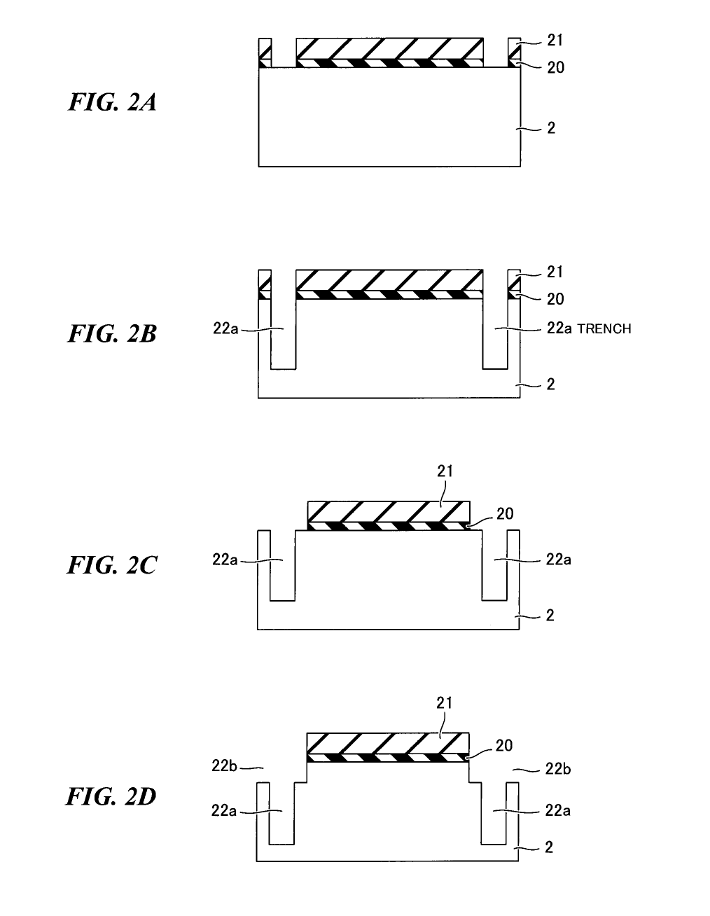

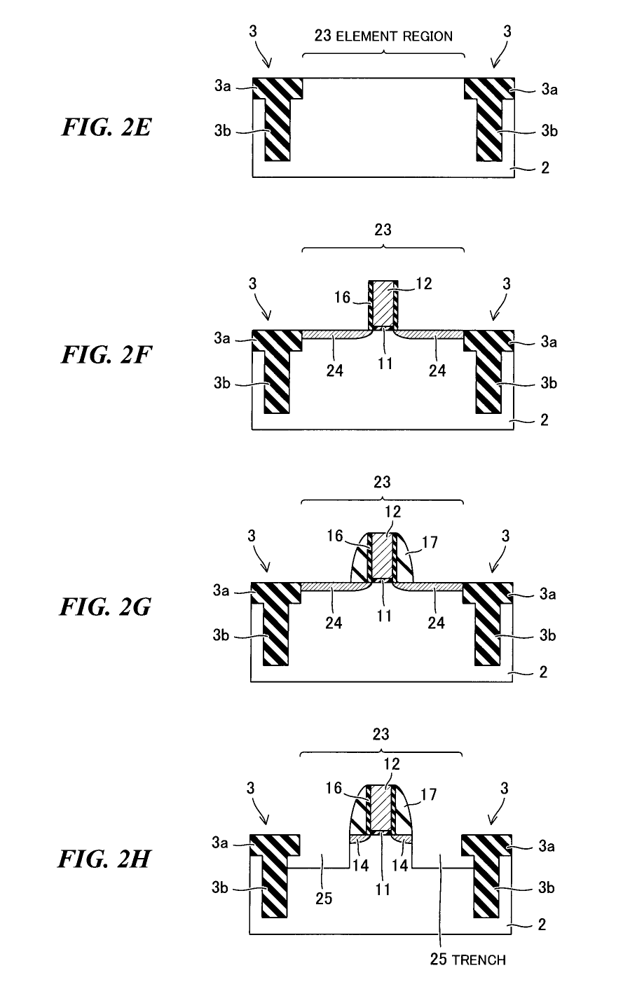

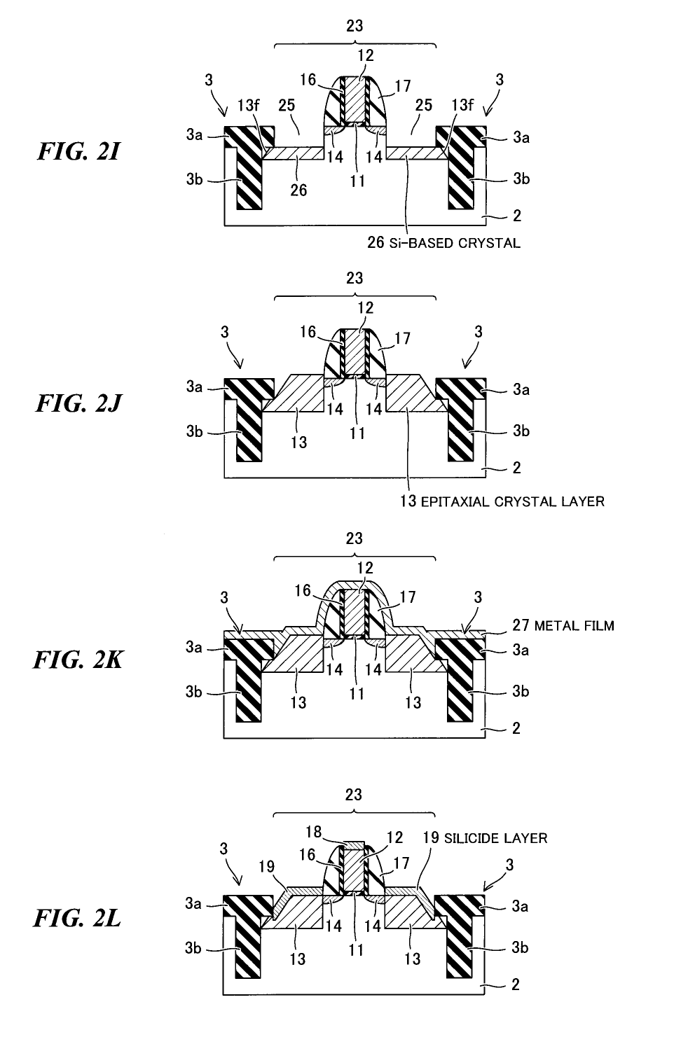

FIGS. 2A to 2L are cross sectional views showing processes for fabricating the semiconductor device 1 according to the embodiment.

Firstly, as shown in FIG. 2A, masks 20 and 21 having a pattern of the lower layer 3b of the element isolation insulating film 3 are formed on the semiconductor substrate 2. For example, the masks 20 and 21 are respectively made of SiO₂ and SiN.

Next, as shown in FIG. 2B, the semiconductor substrate 2 is etched by using the masks 20 and 21 as an etching mask, thereby forming a trench 22a having the pattern of the lower layer 3b.

Next, as shown in FIG. 2C, an opening of the masks 20 and 21 is enlarged by process using H₃PO₄ (phosphoric acid), thereby forming a pattern of the upper layer 3a of the element isolation insulating film 3.

Next, as shown in FIG. 2D, the semiconductor substrate 2 is etched by using the masks 20 and 21 as an etching mask, thereby forming a trench 22b having the pattern of the upper layer 3a.

Here, a region surrounded by the trenches 22a and 22b on the semiconductor substrate 2 is an element region 23 on which the MISFET 10 is formed. The trench 22b has a shallower depth than the trench 22a. In addition, a horizontal distance between the trench 22b and the element region 23 (a horizontal distance between a horizontal edge of the trench 22b on the element region 23 side and a horizontal edge of the element region 23 on the trench 22b side) is smaller than a horizontal distance between the trench 22a and the element region 23 (a horizontal distance between a horizontal edge of the trench 22a on the element region 23 side and a horizontal edge of the element region 23 on the trench 22a side).

Next, as shown in FIG. 2E, the element isolation insulating film 3 is formed in the trenches 22a and 22b after removal of the masks 20 and 21.

For example, after a material of the element isolation insulating film 3 is deposited on the semiconductor substrate 2 so as to fill in the trenches 22a and 22b, a portion of the material outside of the trenches 22a and 22b is removed by planarization process such as Chemical Mechanical Polishing (CMP), thereby forming the element isolation insulating film 3. In addition, a well (not shown) maybe formed in the element region 23 after the formation of the element isolation insulating film 3.

Here, a portion of the element isolation insulating film 3 in the trench 22b is the upper layer 3a, and a portion in the trench 22a is the lower layer 3b. Accordingly, a horizontal distance between the upper layer 3a and the element region 23 (a horizontal distance between a horizontal edge of the upper layer 3a on the element region 23 side and a horizontal edge of the element region 23 on the element isolation insulating film 3 side) is smaller than a horizontal distance between the lower layer 3b and the element region 23 (a horizontal distance between a horizontal edge of the lower layer 3b on the element region 23 side and a horizontal edge of the element region 23 on the element isolation insulating film 3 side).

Next, as shown in FIG. 2F, the gate insulating film 11, the gate electrode 12 and the offset spacer 16 are formed on element region 23 surrounded by the element isolation insulating film 3 on the semiconductor substrate 2, and shallow regions 24 of the source/drain regions are formed on an both sides of the gate electrode 12 in the semiconductor substrate 2.

For example, material films of the gate insulating film 11 and the gate electrode 12 are patterned after the material films are formed on the semiconductor substrate 2, thereby forming the gate insulating film 11 and gate electrode 12. Furthermore, a material film of the offset spacer 16 is shaped by anisotropic etching such as Reactive Ion Etching (RIE) after the material film is formed so as to cover a surface of the gate electrode 12, thereby forming the offset spacer 16. In addition, a conductivity type impurity is implanted into the element region 23 on the semiconductor substrate 2 by using the gate electrode 12 and the offset spacer 16 as an etching mask, thereby forming the shallow regions 24.

Next, as shown in FIG. 2G, the gate sidewall 17 is formed on the side surfaces of the offset spacer 16.

For example, a material film of the gate sidewall 17 is shaped by anisotropic etching such as RIE after the material film is formed so as to cover surfaces of the gate electrode 12 and the offset spacer 16, thereby forming the gate sidewall 17.

Next, as shown in FIG. 2H, the element region 23 on the semiconductor substrate 2 is etched by using the gate electrode 12, the offset spacer 16 and the gate sidewall 17 as an etching mask, thereby forming trenches 25.

Next, as shown in FIG. 2I, Si-based crystals 26 are epitaxially grown by using surfaces of the semiconductor substrate 2 exposed in the trenches 25 as a base. FIG. 2I shows a state of the Si-based crystals 26 at a stage that the grown Si-based crystals 26 contact with the upper layer 3a.

The Si-based crystal 26 is mainly grown in a plane direction of a upper surface thereof, and then the facet 13f appears on the element isolation insulating film 3 side. Note that, the Si-based crystal 26 is not grown from a surface of the element isolation insulating film 3. In addition, a growth rate of the Si-based crystal 26 in a plane direction of the facet 13f is markedly lower than a growth rate in the plane direction of the upper surface thereof.

For example, when a SiGe crystal is used as the Si-based crystal 26, the SiGe crystal is grown in an atmosphere containing mono-silane (SiH₄), dichlorosilane (SiHCl₂), germanium hydride (GeH₄) and the hydrogen gas, etc., under a temperature of 700-750° C.

In addition, a conductivity type impurity can be doped in-situ into the Si-based crystal 26 by adding a gas including the conductivity type impurity to the atmosphere in order to use the epitaxial crystal layer 13 as apart of the source/drain region. When in-situ doping is not carried out, the conductivity type impurity may be implanted into the Si-based crystal 26 by ion-implantation technique after the crystal growth.

Next, as shown in FIG. 2J, the growth of the Si-based crystal 26 is continued, and then the epitaxial crystal layer 13 is obtained. Here, since a part of the upper layer 3a contacts with the facet 13f, the region of the facet 13f below the contact portion of the facet 13f with the upper layer 3a is covered by the element isolation insulating film 3, and thus only the region above the contact portion is exposed outside.

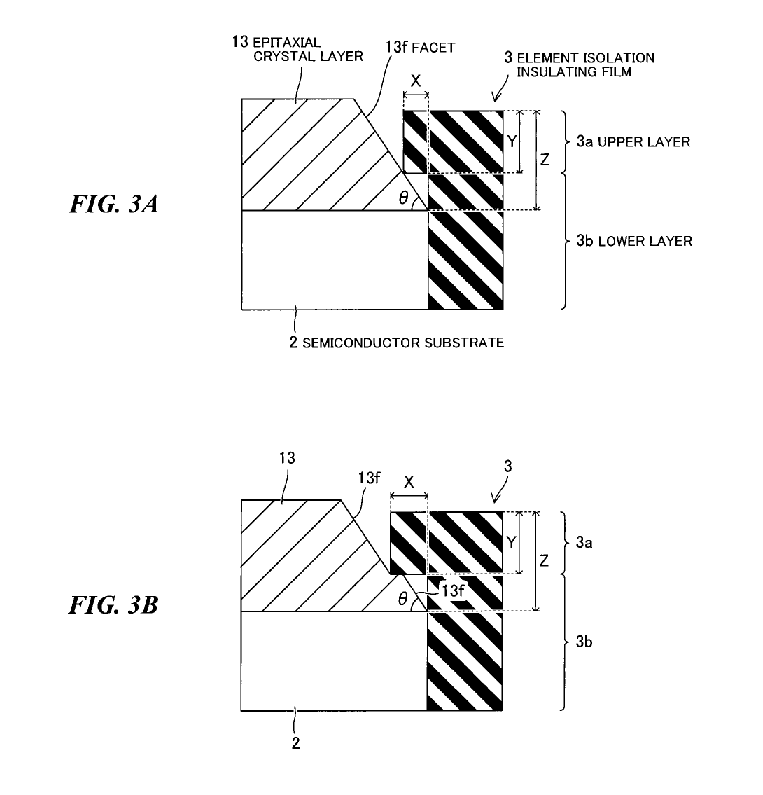

FIGS. 3A and 3B are enlarged view around the contact portion of the epitaxial crystal layer 13 with the upper layer 3a. “X” in FIGS. 3A and 3B shows a horizontal distance between an edge on the gate electrode 12 side of the upper layer 3a and that of the lower layer 3b. “Y” shows a thickness of the upper layer 3a. “Z” shows a vertical distance between an upper surface of the upper layer 3a and a bottom surface of the epitaxial crystal layer 13. In addition, “θ” shows an elevation angle of the facet 13f, which is an angle of the facet 13f with respect to the horizontal surface.

These physical quantities meet relations expressed by the next formula (1).

Z−Y≦X·tan θ (1)

FIG. 3A shows a shape of the epitaxial crystal layer 13 when the right-hand side and the left-hand side of the formula (1) are equal. In this case, a part of the upper layer 3a (the bottom left corner of the upper layer 3a in FIG. 3A) just contacts with the epitaxial crystal layer 13, and thus the region of the facet 13f above the contact portion of the facet 13f with the upper layer 3a and the region below the contact portion constitute an approximately consecutive plane.

FIG. 3B shows a shape of the epitaxial crystal layer 13 when the right-hand side of the formula (1) is larger than the left-hand side. In this case, as shown in FIGS. 2I and 2J, the growth of the Si-based crystal 26 continues in an inside area of the upper layer 3a after the upper surface of the Si-based crystal 26 contacts with a lower surface of the upper layer 3a. As a result, the facet 13f is divided into two discontinuous regions, which are the region of the facet 13f above the contact portion of the facet 13f with the upper layer 3a and the region below the contact portion. Here, the upper layer 3a contacts with a bottom edge of the upper region of the facet 13f as well as a top edge of the lower region of the facet 13f.

Next, as shown in FIG. 2K, a metal film 27 made of Ni, etc., is deposited by sputtering so as to cover exposed surfaces of the gate electrode 12 and the epitaxial crystal layer 13.

In this step, the region of the facet 13f below the contact portion of the epitaxial crystal layer 13 with the upper layer 3a does not contact with the metal film 27 because the region is covered by the element isolation insulating film 3.

Next, as shown in FIG. 2L, silicidation reaction is generated at a contact portion of the metal film 27 with the gate electrode 12 and at a contact portion of the metal film 27 with the epitaxial crystal layer 13 by heat treatment, thereby forming the silicide layer 18 on the upper surface of the gate electrode 12 and forming the silicide layer 19 on the upper surface of the epitaxial crystal layer 13 and on the region of the facet 13f above the contact portion of the facet 13f with the upper layer 3a. Unreacted parts of the metal film 27 are removed by etching.

According to the embodiment, since the silicide layer 19 is selectively formed on the region of the facet 13f above the contact portion of the facet 13f with the upper layer 3a and is not formed on the region below the contact portion, a distance between the semiconductor substrate 2 under the epitaxial crystal layer 13 and the silicide layer 19 is large. Therefore, generation of junction leakage can be suppressed.

In particular, when a SiGe crystal is used as the epitaxial crystal layer 13, there is a serious risk of generation of junction leakage because a metal silicide formed by silicidation of the SiGe crystal may be abnormally grown toward the semiconductor substrate 2 under the epitaxial crystal layer 13 due to thermodynamic instability thereof. Therefore, the embodiment is especially effective when a SiGe crystal is used as the epitaxial crystal layer 13.

In addition, after the process to form the element isolation insulating film 3 shown in FIG. 2E, a SiGe crystal may be epitaxially grown on the element region 23 on the semiconductor substrate 2 and used as a part of the channel region.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a transistor containing a gate electrode and an epitaxial crystal layer, the gate electrode being formed on a semiconductor substrate via a gate insulating film, the epitaxial crystal layer being formed on at least one side of the gate electrode in the semiconductor substrate and including a facet having a different plane direction from a principal plane of the semiconductor substrate;
an element isolation insulating film formed in the semiconductor substrate and electrically isolating the transistor from other elements, the element isolation insulating film containing a lower layer and an upper layer on the lower layer, a horizontal distance between the upper layer and the gate electrode being smaller than a horizontal distance between the lower layer and the gate electrode, a part of the upper layer contacting with the facet; and
a metal silicide layer formed on an upper surface of the epitaxial crystal layer and on a region of the facet above a contact portion of the facet with the upper layer.

2. The semiconductor device according to claim 1, wherein a lowest portion of the metal silicide layer is located in the epitaxial crystal layer.

3. The semiconductor device according to claim 2, wherein the transistor is a p-type transistor; and
the epitaxial crystal layer is made of SiGe crystal.

4. The semiconductor device according to claim 2, wherein the transistor is a n-type transistor; and
the epitaxial crystal layer is made of SiC crystal.

5. The semiconductor device according to claim 2, wherein the semiconductor substrate is a Si-based crystal substrate having a principal surface of which a plane direction is {100}; and
a channel direction of the transistor is <110>.

6. The semiconductor device according to claim 2, wherein a horizontal distance between a horizontal edge of the upper layer on the gate electrode side and a horizontal edge of the lower layer on the gate electrode side is shown as “X”;
a thickness of the upper layer is shown as “Y”;
a vertical distance between an upper surface of the upper layer and a bottom surface of the epitaxial crystal layer is shown as “Z”;
an elevation angle of the facet is shown as “θ”; and
Z−Y≦X*tan θ.

7. The semiconductor device according to claim 2, wherein the facet contains a first region above the contact portion and the second region below the contact portion; and
the first region and the second region are discontinuous.

8. The semiconductor device according to claim 1, wherein the transistor is a p-type transistor; and
the epitaxial crystal layer is made of SiGe crystal.

9. The semiconductor device according to claim 1, wherein the transistor is a n-type transistor; and
the epitaxial crystal layer is made of SiC crystal.

10. The semiconductor device according to claim 1, wherein the semiconductor substrate is a Si-based crystal substrate having a principal surface of which a plane direction is {100}; and
a channel direction of the transistor is <110>.

11. The semiconductor device according to claim 1, wherein a horizontal distance between a horizontal edge of the upper layer on the gate electrode side and a horizontal edge of the lower layer on the gate electrode side is shown as “X”;
a thickness of the upper layer is shown as “Y”;
a vertical distance between an upper surface of the upper layer and a bottom surface of the epitaxial crystal layer is shown as “Z”;
an elevation angle of the facet is shown as “e”; and
Z−Y≦X·tan θ.

12. The semiconductor device according to claim 1, wherein the facet contains a first region above the contact portion and the second region below the contact portion; and
the first region and the second region are discontinuous.

13. A method of fabricating a semiconductor device, comprising:
forming an element isolation trench in a semiconductor substrate so as to surround an element region on the semiconductor substrate, the element isolation trench containing a lower region and an upper region on the lower region, a horizontal distance between the upper region and the element region being smaller than a horizontal distance between the lower region and the element region;
filling the element isolation trench by an insulating film, thereby forming an element isolation insulating film, the element isolation insulating film containing a lower layer and an upper layer on the lower layer, a horizontal distance between the upper layer and the element region being smaller than a horizontal distance between the lower layer and the element region;
forming a gate electrode on the element region, which is surrounded by the element isolation insulating film, via a gate insulating film;
forming a trench on at least one side of the gate electrode in the semiconductor substrate in the element region;
epitaxially growing a crystal using a surface of the semiconductor substrate exposed in the trench as a base so that a facet thereof having a different plane direction from a principal plane of the semiconductor substrate contacts with the upper layer of the element isolation insulating film; and
forming a metal silicide layer on an upper surface of the crystal and on a region of the facet above a contact portion of the facet with the upper layer.

14. The method of fabricating a semiconductor device according to claim 13, wherein the metal silicide layer is formed so that a lowest portion thereof is located in the epitaxial crystal layer.

15. The method of fabricating a semiconductor device according to claim 14, wherein the crystal is a SiGe crystal; and
the gate insulating film, the gate electrode, the crystal and the metal silicide layer constitutes a p-type transistor.

16. The method of fabricating a semiconductor device according to claim 14, wherein the crystal is a SiC crystal; and
the gate insulating film, the gate electrode, the crystal and the metal silicide layer constitutes an n-type transistor.

17. The method of fabricating a semiconductor device according to claim 14, wherein the semiconductor substrate is a Si-based crystal substrate having a principal surface of which a plane direction is {100}; and
a gate-length direction of the gate electrode is <110>.

18. The method of fabricating a semiconductor device according to claim 13, wherein the crystal is a SiGe crystal; and
the gate insulating film, the gate electrode, the crystal and the metal silicide layer constitutes a p-type transistor.

19. The method of fabricating a semiconductor device according to claim 13, wherein the crystal is a SiC crystal; and
the gate insulating film, the gate electrode, the crystal and the metal silicide layer constitutes an n-type transistor.

20. The method of fabricating a semiconductor device according to claim 13, wherein the semiconductor substrate is a Si-based crystal substrate having a principal surface of which a plane direction is {100}; and
a gate-length direction of the gate electrode is <110>.
